(19) United States
(12) Patent Application Publication
(10) Pub. No.: US 2026/0324338 A1
(43) Pub. Date: Oct. 15, 2026

(54) VAPORIZING SYSTEM

(71) Applicant: MERCK PATENT GmbH, DARMSTADT (DE)

(72) Inventor: JAE-SEOUNG CHO, SEJONG CITY (KR)

(21) Appl. No.: 19/644,405

(22) Filed: Apr. 10, 2026

Related U.S. Application Data
(60) Provisional application No. 63/787,204, filed on Apr. 11, 2025.

(51) Int. Cl. H10P 72/00

(52) U.S. Cl. CPC H10P 72/0402; H10P 72/06

(57) ABSTRACT

A semiconductor manufacturing vaporizing system is disclosed. The system may comprise a first-gas-conduit, a buffer tank positioned upstream of and fluidly coupled to the first-gas-conduit configured to store a first material in a gaseous state at a first pressure, and a second-gas-conduit upstream of and fluidly coupled to the buffer tank configured to convey a gas-stream to the buffer tank. The system may also include a vaporizer upstream of and fluidly coupled to the second-gas-conduit configured to induce a phase change with respect to the first material. The system may additionally include a first-liquid-conduit upstream of and fluidly coupled to the vaporizer configured to convey a pressurized-liquid-stream of the first-material. A pump is positioned fluidly upstream of the first-liquid-conduit that is configured to receive a non-pressurized-liquid-stream of the first-material and propel it toward the vaporizer via the first-liquid-conduit. The system may also include a second-liquid-conduit fluidly coupled to the pump.

### CROSS REFERENCE TO RELATED APPLICATION

This application claims priority to U.S. provisional application No. 63/787,204, filed Apr. 11, 2025, which is hereby incorporated by reference in its entirety.

### TECHNICAL FIELD

This disclosure generally relates to a semiconductor manufacturing process, and more particularly to a vaporizing system for the semiconductor manufacturing process.

### BACKGROUND

Semiconductor manufacturing materials may be stored as a liquid phase material that requires conversion to a gas phase material before use in a particular manufacturing process. Current systems designed to store liquid phase materials and convert such materials to gas phase before use in semiconductor manufacturing processes often utilize a positive displacement pump, such as a plunger or piston pump. These pumps often fail before their anticipated life expectancy. The present disclosure is directed to overcoming one or more problems set forth above, and/or other problems associated with the prior art pumps used in semiconductor manufacturing process vaporizing systems.

### SUMMARY OF THE INVENTION

In accordance with a first aspect of the present application, a vaporizing system for a semiconductor manufacturing process is disclosed. The vaporizing system may comprise a first-gas-conduit configured to convey a gas-stream of a first-material toward the semiconductor manufacturing process, a buffer tank upstream of and fluidly coupled to the first-gas-conduit configured to store the first-material in a gaseous state at, or above, a predetermined low-pressure-value, and a second-gas-conduit located upstream of and fluidly coupled to the buffer tank configured to convey the gas-stream of the first material toward the buffer tank. In addition, the vaporizing system may contain a vaporizer situated upstream of and fluidly coupled to the second-gas-conduit configured to induce a phase change of the first-material from a liquid state to a gaseous state and thereby create the gas-stream of the first-material, and a first-liquid-conduit upstream of and fluidly coupled to the vaporizer configured to convey a pressurized-liquid-stream of the first-material toward the vaporizer. A pump may be positioned upstream of and fluidly coupled to the first-liquid-conduit and be configured to receive a non-pressurized-liquid-stream of the first-material and send out the pressurized-liquid-stream of the first material, thereby propelling the first-material toward the vaporizer, and a second-liquid-conduit can be positioned upstream of and fluidly coupled to the pump configured to convey the non-pressurized-liquid-stream of the first-material to the pump.

In accordance with a second aspect of this disclosure, a gas supply system for a semiconductor manufacturing process is disclosed. The gas supply system may comprise a liquid material tank upstream of, and fluidly connected to, a second-liquid-conduit, and the liquid material tank may be configured to store a first-material in a liquid state, and the second-liquid-conduit may be configured to convey a non-pressurized-liquid-stream of the first-material toward the remainder of the gas supply system. It can additionally include a pressure control and purification system downstream of, and fluidly connected to a first-gas-conduit, wherein the pressure control and purification system is configured to receive a gas-stream of the first-material through the first-gas-conduit and generate a process-ready-gas-stream has a pressure equivalent to a predetermined-manufacturing-process-pressure defined by the semiconductor manufacturing process, and wherein the process-ready-gas-stream further has a total-particle-count less than, or equal to, a predetermined particle-count defined by the semiconductor manufacturing process.

In this second aspect, a process-ready-gas-conduit is located downstream of, and fluidly coupled to, the pressure control and purification system, and upstream of, and fluidly coupled to, the semiconductor manufacturing process that is configured to convey the process-ready-gas-stream from the pressure control and purification system to the semiconductor manufacturing process.

This gas supply system may additionally include a vaporizing system. The vaporizing system may comprise a first-gas-conduit configured to convey a gas-stream of a first-material toward the semiconductor manufacturing process, a buffer tank upstream of and fluidly coupled to the first-gas-conduit configured to store the first-material in a gaseous state at, or above, a predetermined low-pressure-value, and a second-gas-conduit located upstream of and fluidly coupled to the buffer tank configured to convey the gas-stream of the first material toward the buffer tank. In addition, the vaporizing system may contain a vaporizer situated upstream of and fluidly coupled to the second-gas-conduit configured to induce a phase change of the first-material from a liquid state to a gaseous state and thereby create the gas-stream of the first-material, and a first-liquid-conduit upstream of and fluidly coupled to the vaporizer configured to convey a pressurized-liquid-stream of the first-material toward the vaporizer. A pump may be positioned upstream of and fluidly coupled to the first-liquid-conduit and be configured to receive a non-pressurized-liquid-stream of the first-material and send out the pressurized-liquid-stream of the first material, thereby propelling the first-material toward the vaporizer, and a second-liquid-conduit can be positioned upstream of and fluidly coupled to the pump configured to convey the non-pressurized-liquid-stream of the first-material to the pump.

Lastly, and in accordance with a third aspect of this application, a method of operating a gas supply system to create a process-ready-gas-stream for a semiconductor manufacturing process is described. The method may include fluidly coupling a liquid material tank configured to store a first-material in a liquid state with a second-liquid-conduit configured to convey a non-pressurized-liquid-stream of the first-material, wherein the second-liquid-conduit is positioned fluidly downstream of the liquid material tank. Next, the method of operation includes fluidly coupling the second-liquid-conduit configured to convey the non-pressurized-liquid-stream of the first-material with a pump. The pump may be configured to receive the non-pressurized-liquid-stream of the first-material and send-out a pressurized-liquid-stream of the first-material, and the pump is positioned fluidly downstream of the second-liquid-conduit. This method also includes fluidly coupling the pump configured to send-out the pressurized-liquid-stream of the first-material with a first-liquid-conduit configured to convey the pressurized-liquid-stream of the first-material. The first-liquid-conduit may be positioned fluidly downstream of the pump. Additionally, the method comprises fluidly coupling the first-liquid-conduit configured to convey the pressurized-liquid-stream of the first-material to a vaporizer that is configured to induce a phase change of the first-material from a liquid state to a gaseous state and thereby create a gas-stream of the first material. The vaporizer may be positioned fluidly downstream of first-liquid-conduit.

This method also includes fluidly coupling the vaporizer configured to induce a phase change of the first-material from a liquid state to a gaseous state and thereby create a gas-stream of the first material with a second-gas-conduit configured to convey the gas-stream, wherein the second-gas-conduit is positioned fluidly downstream of the vaporizer. In another step, the second-gas-conduit configured to convey the gas-stream is fluidly coupled with a buffer tank that is configured to store the first-material in a gaseous-state, and wherein the buffer tank is positioned fluidly downstream of the second-gas-conduit. This method may also incorporate fluidly coupling the buffer tank with a first-gas-conduit configured to convey the gas-stream with a pressure control and purification system configured to receive the gas-stream and generate a process-ready-gas-stream for the semiconductor manufacturing process. The pressure control and purification system is located fluidly downstream of the first-gas-conduit. In another step of this process, the buffer tank is fluidly coupled with a process-ready-gas-conduit configured to convey the process-ready-gas-stream towards the semiconductor manufacturing process, wherein the process-ready-gas-conduit is positioned fluidly downstream of the process-ready-gas-conduit.

The semiconductor manufacturing process may be fluidly coupled with the process-ready-gas-conduit configured to convey the process-ready-gas-stream towards the semiconductor manufacturing process, and the semiconductor manufacturing process is positioned fluidly downstream of the process-ready-gas-conduit. A pressure sensor may be associated with the buffer tank that is configured to transmit a pressure signal to the electronic controller while the pressure sensor detects that the pressure of the first-material in the buffer tank is less than a predetermined low-pressure value. The electronic controller is further configured to transmit a supply signal to the pump while the pressure of the first-material in the buffer tank is less than a predetermined low-pressure value and thereby propel the first-material toward the remainder of the gas supply system, and wherein the electronic controller is additionally configured to stop sending the supply signal to the pump when the pressure of the first-material in the buffer tank is greater than, or equal to, the predetermined low-pressure value.

### BRIEF DESCRIPTION OF THE DRAWINGS

FIG. 1 is a block diagram of an exemplary gas supply system for a semiconductor manufacturing process manufactured in accordance with an aspect of the present disclosure.

FIG. 2 is a block diagram of an exemplary vaporizing system that may be utilized with the exemplary gas supply system manufactured in accordance with FIG. 1.

FIG. 3 is a cross-sectional view of an exemplary pump that may be employed with the exemplary vaporizing system depicted in FIG. 2.

FIG. 4 is a block diagram of an exemplary control system that may be applied to the vaporizing system of FIG. 2 as well as the gas supply system of FIG. 1.

FIG. 5 is flowchart depicting an exemplary sample sequence of steps of the control system of the gas supply system manufactured in accordance with FIGS. 1-4.

### DETAILED DESCRIPTION OF THE DISCLOSURE

Example embodiments will be described more fully with reference to the accompanying drawings. Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected, or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer, or section. Terms such as “first,” “second,” and other numerical terms when used herein do not imply a sequence or order unless clearly indicated by the context. Thus, a first step, element, component, region, layer, or section discussed below could be termed a second step, element, component, region, layer, or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges. Thus, ranges are, unless specified otherwise, inclusive of endpoints and include disclosure of all distinct values and further divided ranges within the entire range. Disclosure of values and ranges of values for specific parameters (such as temperatures, molecular weights, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping, or distinct) subsume all possible combination of ranges for the value that might be claimed using endpoints of the disclosed ranges.

For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

As used herein, the terms “composition” and “material” are used interchangeably to refer broadly to a substance containing at least the preferred chemical constituents, elements, or compounds, but which may also comprise additional elements, compounds, or substances, including trace amounts of impurities, unless otherwise indicated.

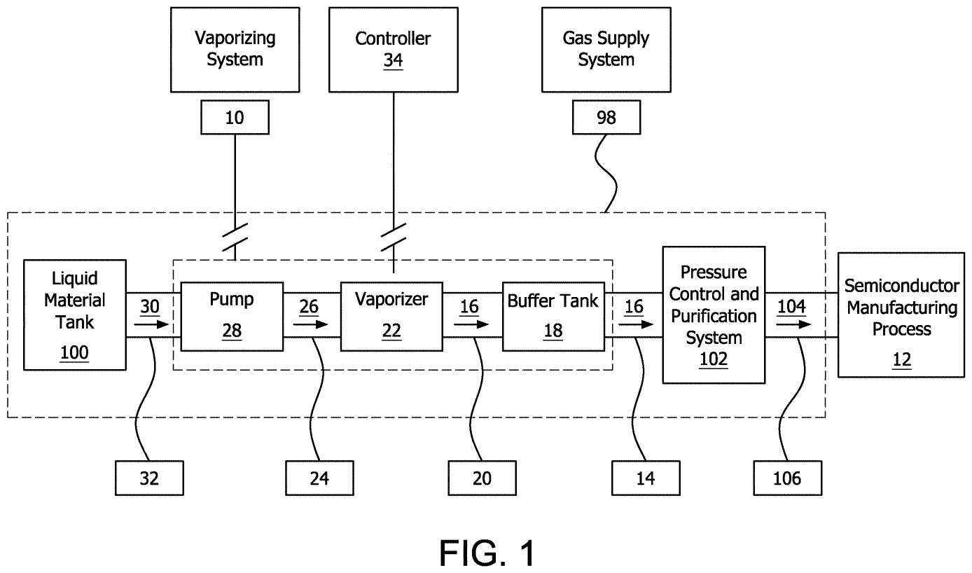

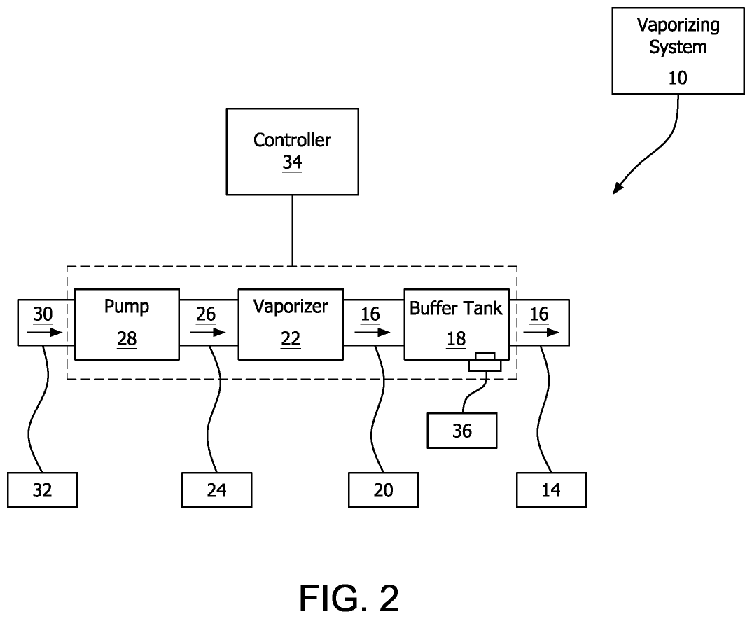

Various aspects of the disclosure will now be described with reference to the drawings and tables disclosed herein, if applicable, with like reference numbers referring to like elements, unless specified otherwise. Turning now to FIGS. 1 and 2, a vaporizing system 10 of a gas supply system 98 for a semiconductor manufacturing process 12 is depicted. This gas supply system 98 may be for any number of gases utilized in semiconductor manufacturing processes including, but not limited to, oxygen (O₂), nitrogen (N₂), Argon (Ar), carbon dioxide (CO₂) and supercritical carbon dioxide (CO₂). As seen in these figures, the vaporizing system 10 may include a first-gas-conduit 14 configured to convey a gas-stream 16 of a first-material toward the semiconductor manufacturing process 12, and a buffer tank 18 located upstream of and fluidly coupled to the first-gas-conduit 14 configured to store the first-material in a gaseous state at, or above, a predetermined low-pressure-value. The vaporizing system 10 may additionally comprise a second-gas-conduit 20 situated upstream of and fluidly coupled to the buffer tank 18 configured to convey the gas-stream 16 of the first material toward the buffer tank 18, and a vaporizer 22 placed upstream of and fluidly coupled to the second-gas-conduit 20 that is configured to induce a phase change of the first-material from a liquid state to a gaseous state and thereby create the gas-stream 16 of the first-material.

Additionally, the vaporizing system 10 contains a first-liquid-conduit 24 located upstream of and fluidly coupled to the vaporizer 22 that is configured to convey a pressurized-liquid-stream 26 of the first-material toward the vaporizer 22, and also comprise a pump 28 upstream of and fluidly coupled to the first-liquid-conduit 24 configured to receive a non-pressurized-liquid-stream 30 of the first-material and send out the pressurized-liquid-stream 26 of the first material, thereby propelling the first-material toward the vaporizer 22. In an additional feature of this system 10, it may include a second-liquid-conduit 32 placed upstream of and fluidly coupled to the pump 28 configured to convey the non-pressurized-liquid-stream 30 of the first-material to the pump 28.

The vaporizing system 10 may further comprise an electronic controller 34 configured to receive a low-pressure-signal and transmit a supply signal to the pump 28 in response to the low-pressure-signal, and further comprise a pressure sensor 36 associated with the buffer tank 18 configured to transmit the low-pressure-signal to the electronic controller 34 when it detects that the pressure of the first-material in the buffer tank 18 is less than the predetermined low-pressure-value. In this instance, the pump 28 may be configured to propel the first-material toward the remainder of the vaporizing system 10 while receiving the supply signal from the electronic controller 34 and stop propelling the first-material toward the remainder of the vaporizing system 10 when it does not receive the supply signal from the electronic controller 34.

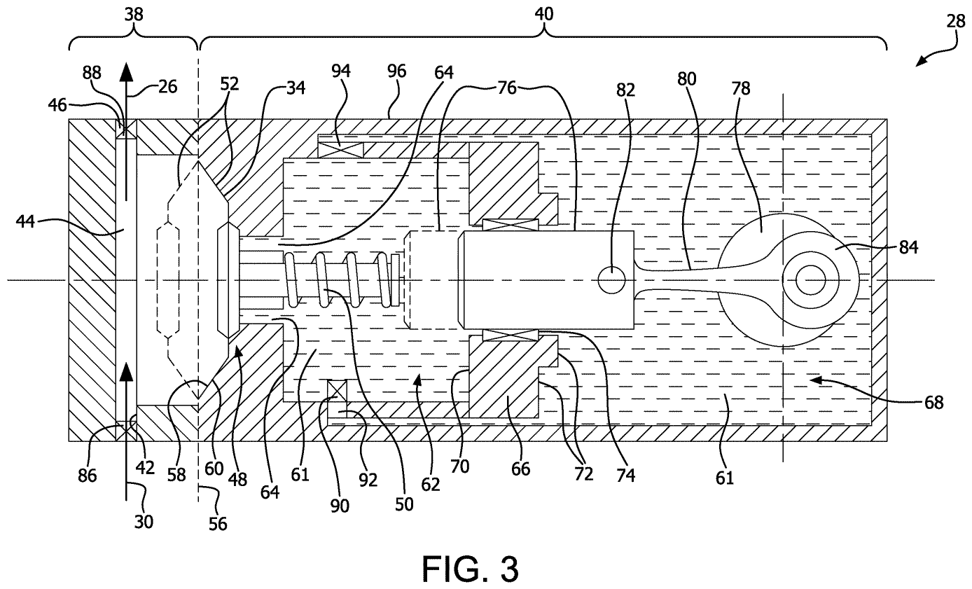

Now turning to FIG. 3, the pump 28 of the vaporizing system 10 may be a hydraulically-actuated-diaphragm-pump, comprising a fluid-end 38 adjacent a power-end 40. The fluid-end 38 may be configured to allow the flow of the non-pressurized-liquid-stream 30 of the first-material through an inlet-port 42 into a fluid-end-chamber 44, and wherein the fluid-end 38 is further configured to allow the flow of the pressurized-liquid-stream 26 of the first-material out of the fluid-end-chamber 44 through an outlet-port 46. The power-end 40 may be configured to conduct work on the non-pressurized-liquid-stream 30 of the first-material residing inside the fluid-end-chamber 44 and thereby create the pressurized-liquid-stream 26 of the first-material by the action of a hydraulically-actuated-diaphragm 48.

The hydraulically-actuated-diaphragm 48 of the pump 28 may be reciprocally attached to the power-end 40, and be able to actuate between a diaphragm-resting-state that exists while a return-spring 50 of the hydraulically-actuated-diaphragm 48 is in a non-tensioned position and a diaphragm 52 is abutting a power-end-fluid-chamber-wall 54, and a diaphragm-pressurization-state that exists while the return-spring 50 is in a tensioned position and at least a portion of the diaphragm 52 extends past a pressurization-line 56. The pressurization-line 56 can be defined as a plane extending through the location where the fluid-end 38 abuts the power-end 40. The hydraulically-actuated-diaphragm 48 conducts work on the non-pressurized-liquid-stream 30 of the first-material residing inside the fluid-end-chamber 44 and thereby creates the pressurized-liquid-stream 26 of the first-material when actuated from the diaphragm-resting-state to the diaphragm-pressurization-state.

The hydraulically-actuated-diaphragm 48 of the vaporizing system 10 may further comprise a front-side 58 in contact with the first-material, a back-side 60 opposite the front-side 58 in contact with a hydraulic-fluid 61 held inside a power-end-hydraulic-chamber 62, and an orifice 64 extending between the power-end-hydraulic-chamber 62 and the back-side 60. The orifice 64 may be configured to transfer the hydraulic-fluid 61 to the back-side 60 while the hydraulic-fluid 61 is under pressure inside the power-end-hydraulic-chamber 62.

The power-end 40 of the pump 28 may further comprise a separation-wall 66 dividing the power-end-hydraulic-chamber 62 from an overflow-chamber 68 having a front-end 70 neighboring the power-end-hydraulic-chamber 62 and a back-end 72 opposite the front-end 70 neighboring the overflow-chamber 68. A bore 74 may extend through the separation-wall 66 between the front-end 70 and the back-end 72, a plunger 76 may be reciprocally engaged with the bore 74. A crankshaft 78 may be rotationally powered by a motor, and a connecting-rod 80 can be operatively coupled to the plunger 76 at its first-end 82 and further operatively coupled to the crankshaft 78 at its second-end 84.

The reciprocally engaging plunger 76 may actuate between a plunger-resting-state that exists while the second-end 84 of the connecting-rod 80 is positioned at a location furthest away from the front-end 70 of the separation-wall 66 and a plunger-pressurization-state that exists while the second-end 84 of the connecting-rod 80 is positioned at a location closest to the front-end 70 of the separation-wall 66. The reciprocally engaging plunger 76 conducts work on the hydraulic-fluid 61 inside the power-end-hydraulic-chamber 62 while transitioning from the plunger-resting-state to the plunger-pressurization state, thereby propelling hydraulic-fluid 61 located inside the power-end-hydraulic-chamber 62 through the orifice 64 to the back-side 60 of the hydraulically-actuated-diaphragm 58 so that the hydraulically-actuated-diaphragm 58 may actuate between the diaphragm-resting-state and diaphragm-pressurization-state, thereby conducting work on the non-pressurized-liquid-stream 30 of the first-material residing inside the fluid-end-chamber 44 and thereby create the pressurized-liquid-stream 26 of the first-material inside the fluid-end-chamber 44.

The pump 28 may further include a first-check-valve 86 associated with the inlet-port 42 that is configured to allow flow of the non-pressurized-liquid-stream 30 into the fluid-end-chamber 44 while the pressure of the first-material inside the fluid-end-chamber 44 is less than, or equal to, a first-predetermined-value. The pump 28 may also include a second-check-valve 88 associated the outlet-port 46 that is configured to allow flow of the pressurized-liquid-stream 26 of the first-material out of the fluid-end-chamber 44 while the pressure of the first-material inside the fluid-end-chamber 44 is greater than, or equal to, a second-predetermined-value. The second-predetermined value is greater than the first-predetermined-value.

The pump 28 can further include a third-check-valve 90 associated with a hydraulic-fluid-inlet-port 92 configured to allow flow of the hydraulic-fluid 61 into the power-end-hydraulic-chamber 62 while the pressure of the hydraulic-fluid 61 inside the power-end-hydraulic-chamber 62 is less than, or equal to, a third-predetermined-value. The pump can further comprise a fourth-check-valve 94 associated with a hydraulic-fluid-outlet-port 96 configured to allow flow of the hydraulic-fluid 61 out of the power-end-hydraulic-chamber 62 while the pressure of the hydraulic-fluid 61 inside the power-end-hydraulic-chamber 62 is greater than, or equal to, a fourth-predetermined-value. The fourth-predetermined-value is greater than the third-predetermined-value.

Referring to FIGS. 1 and 2 again, the gas supply system 98 for a semiconductor manufacturing process 12 may additionally include a liquid material tank 100 positioned upstream of, and fluidly connected to, a second-liquid-conduit 32. The liquid material tank 100 is configured to store a first-material in a liquid state, and the second-liquid-conduit 32 is configured to convey a non-pressurized-liquid-stream 30 of the first-material toward the remainder of the gas supply system (98).

The system 98 can also include a pressure control and purification system 102 located downstream of, and fluidly connected to a first-gas-conduit 14 and the pressure control and purification system 102 may be configured to receive a gas-stream 16 of the first-material through the first-gas-conduit 14 and generate a process-ready-gas-stream 104 has a pressure equivalent to a predetermined-manufacturing-process-pressure defined by the semiconductor manufacturing process 12. The process-ready-gas-stream 104 further has a total-particle-count less than, or equal to, a predetermined particle-count defined by the semiconductor manufacturing process 12 too.

The system 98 illustrated in FIG. 2 also includes a process-ready-gas-conduit 106 situated downstream of, and fluidly coupled to, the pressure control and purification system 102, and is further situated and upstream of, and fluidly coupled to, the semiconductor manufacturing process 12 that is configured to convey the process-ready-gas-stream 104 from the pressure control and purification system 102 to the semiconductor manufacturing process 12.

As seen in FIGS. 1 and 2, the gas system 98 may further include a vaporizing system 10 including a first-gas-conduit 14 configured to convey a gas-stream 16 of a first-material toward the semiconductor manufacturing process 12, and a buffer tank 18 located upstream of and fluidly coupled to the first-gas-conduit 14 configured to store the first-material in a gaseous state at, or above, a predetermined low-pressure-value. The vaporizing system 10 may additionally comprise a second-gas-conduit 20 situated upstream of and fluidly coupled to the buffer tank 18 configured to convey the gas-stream 16 of the first material toward the buffer tank 18, and a vaporizer 22 placed upstream of and fluidly coupled to the second-gas-conduit 20 that is configured to induce a phase change of the first-material from a liquid state to a gaseous state and thereby create the gas-stream 16 of the first-material.

Additionally, the vaporizing system 10 contains a first-liquid-conduit 24 located upstream of and fluidly coupled to the vaporizer 22 that is configured to convey a pressurized-liquid-stream 26 of the first-material toward the vaporizer 22, and also comprise a pump 28 upstream of and fluidly coupled to the first-liquid-conduit 24 configured to receive a non-pressurized-liquid-stream 30 of the first-material and send out the pressurized-liquid-stream 26 of the first material, thereby propelling the first-material toward the vaporizer 22. In an additional feature of this system 10, it may include a second-liquid-conduit 32 placed upstream of and fluidly coupled to the pump 28 configured to convey the non-pressurized-liquid-stream 30 of the first-material to the pump 28.

The vaporizing system 10 may further comprise an electronic controller 34 configured to receive a low-pressure-signal and transmit a supply signal to the pump 28 in response to the low-pressure-signal, and further comprise a pressure sensor 36 associated with the buffer tank 18 configured to transmit the low-pressure-signal to the electronic controller 34 when it detects that the pressure of the first-material in the buffer tank 18 is less than the predetermined low-pressure-value. In this instance, the pump 28 may be configured to propel the first-material toward the remainder of the vaporizing system 10 while receiving the supply signal from the electronic controller 34 and stop propelling the first-material toward the remainder of the vaporizing system 10 when it does not receive the supply signal from the electronic controller 34.

Now turning to FIG. 3, the pump 28 of the vaporizing system 10 may be a hydraulically-actuated-diaphragm-pump, comprising a fluid-end 38 adjacent a power-end 40. The fluid-end 38 may be configured to allow the flow of the non-pressurized-liquid-stream 30 of the first-material through an inlet-port 42 into a fluid-end-chamber 44, and wherein the fluid-end 38 is further configured to allow the flow of the pressurized-liquid-stream 26 of the first-material out of the fluid-end-chamber 44 through an outlet-port 46. The power-end 40 may be configured to conduct work on the non-pressurized-liquid-stream 30 of the first-material residing inside the fluid-end-chamber 44 and thereby create the pressurized-liquid-stream 26 of the first-material by the action of a hydraulically-actuated-diaphragm 48.

The hydraulically-actuated-diaphragm 48 of the pump 28 may be reciprocally attached to the power-end 40, and be able to actuate between a diaphragm-resting-state that exists while a return-spring 50 of the hydraulically-actuated-diaphragm 48 is in a non-tensioned position and a diaphragm 52 is abutting a power-end-fluid-chamber-wall 54, and a diaphragm-pressurization-state that exists while the return-spring 50 is in a tensioned position and at least a portion of the diaphragm 52 extends past a pressurization-line 56. The pressurization-line 56 can be defined as a plane extending through the location where the fluid-end 38 abuts the power-end 40. The hydraulically-actuated-diaphragm 48 conducts work on the non-pressurized-liquid-stream 30 of the first-material residing inside the fluid-end-chamber 44 and thereby creates the pressurized-liquid-stream 26 of the first-material when actuated from the diaphragm-resting-state to the diaphragm-pressurization-state.

The hydraulically-actuated-diaphragm 48 of the vaporizing system 10 may further comprise a front-side 58 in contact with the first-material, a back-side 60 opposite the front-side 58 in contact with a hydraulic-fluid 61 held inside a power-end-hydraulic-chamber 62, and an orifice 64 extending between the power-end-hydraulic-chamber 62 and the back-side 60. The orifice 64 may be configured to transfer the hydraulic-fluid 61 to the back-side 60 while the hydraulic-fluid 61 is under pressure inside the power-end-hydraulic-chamber 62.

The power-end 40 of the pump 28 may further comprise a separation-wall 66 dividing the power-end-hydraulic-chamber 62 from an overflow-chamber 68 having a front-end 70 neighboring the power-end-hydraulic-chamber 62 and a back-end 72 opposite the front-end 70 neighboring the overflow-chamber 68. A bore 74 may extend through the separation-wall 66 between the front-end 70 and the back-end 72, a plunger 76 may be reciprocally engaged with the bore 74. A crankshaft 78 may be rotationally powered by a motor, and a connecting-rod 80 can be operatively coupled to the plunger 76 at its first-end 82 and further operatively coupled to the crankshaft 78 at its second-end 84.

The reciprocally engaging plunger 76 may actuate between a plunger-resting-state that exists while the second-end 84 of the connecting-rod 80 is positioned at a location furthest away from the front-end 70 of the separation-wall 66 and a plunger-pressurization-state that exists while the second-end 84 of the connecting-rod 80 is positioned at a location closest to the front-end 70 of the separation-wall 66. The reciprocally engaging plunger 76 conducts work on the hydraulic-fluid 61 inside the power-end-hydraulic-chamber 62 while transitioning from the plunger-resting-state to the plunger-pressurization state, thereby propelling hydraulic-fluid 61 located inside the power-end-hydraulic-chamber 62 through the orifice 64 to the back-side 60 of the hydraulically-actuated-diaphragm 58 so that the hydraulically-actuated-diaphragm 58 may actuate between the diaphragm-resting-state and diaphragm-pressurization-state, thereby conducting work on the non-pressurized-liquid-stream 30 of the first-material residing inside the fluid-end-chamber 44 and thereby create the pressurized-liquid-stream 26 of the first-material inside the fluid-end-chamber 44.

The pump 28 may further include a first-check-valve 86 associated with the inlet-port 42 that is configured to allow flow of the non-pressurized-liquid-stream 30 into the fluid-end-chamber 44 while the pressure of the first-material inside the fluid-end-chamber 44 is less than, or equal to, a first-predetermined-value. The pump 28 may also include a second-check-valve 88 associated the outlet-port 46 that is configured to allow flow of the pressurized-liquid-stream 26 of the first-material out of the fluid-end-chamber 44 while the pressure of the first-material inside the fluid-end-chamber 44 is greater than, or equal to, a second-predetermined-value. The second-predetermined value is greater than the first-predetermined-value.

The pump 28 can further include a third-check-valve 90 associated with a hydraulic-fluid-inlet-port 92 configured to allow flow of the hydraulic-fluid 61 into the power-end-hydraulic-chamber 62 while the pressure of the hydraulic-fluid 61 inside the power-end-hydraulic-chamber 62 is less than, or equal to, a third-predetermined-value. The pump can further comprise a fourth-check-valve 94 associated with a hydraulic-fluid-outlet-port 96 configured to allow flow of the hydraulic-fluid 61 out of the power-end-hydraulic-chamber 62 while the pressure of the hydraulic-fluid 61 inside the power-end-hydraulic-chamber 62 is greater than, or equal to, a fourth-predetermined-value. The fourth-predetermined-value is greater than the third-predetermined-value.

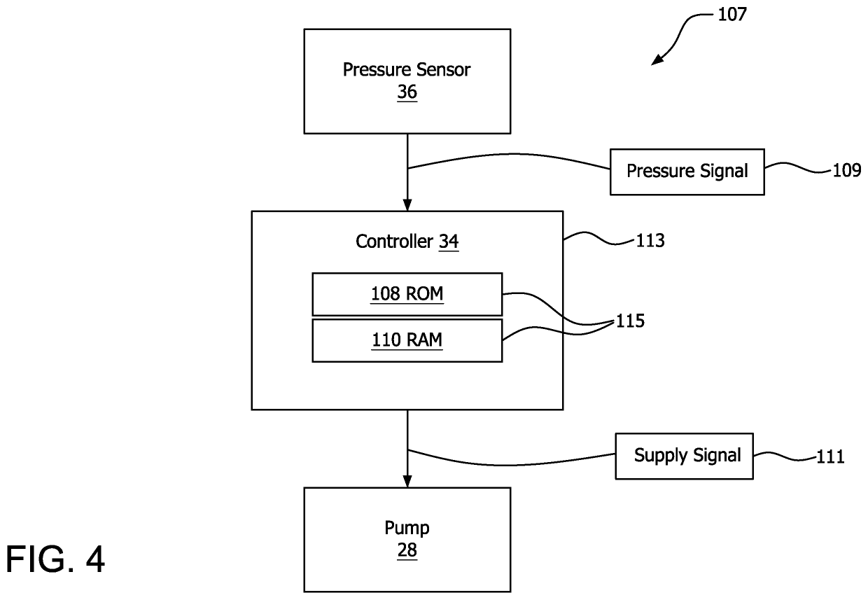

Referring now to FIG. 4 a block diagram of an exemplary control system that may be utilized with the vaporizing system 10 of the gas supply system 98 is illustrated and generally referred to by the reference numeral 107. As seen there, the control system 107 may include a sensor, such as the pressure sensor 36 that is operatively associated with the buffer tank 18 described above. This pressure sensor 36 may also be operatively coupled to the electronic controller 34, and the controller 34 may be configured to receive the pressure signal 109 from the pressure sensor 36. When the pressure signal 109 is less than a preset value, the controller 34 may be configured to transmit a supply signal 111 to the pump 28. In response the pump 28 may send out the pressurized-liquid-stream 26 of the first material toward the vaporizer 22. When the pressure signal 109 is greater than, or equal to, the preset value the controller 34 may stop sending the supply signal 111 to the pump, and thereby the pump 28 may stop sending out the pressurized-liquid-stream 26 of the first material toward the vaporizer 22.

The electronic controller 34 may include a microprocessor 113 for executing specified programs that control and monitor various functions associated with the vaporizing system 10, including receiving the pressure signal 109 and transmitting the supply signal 111 to the pump 28 while the pressure inside the buffer tank 18 is below the preset value. Additionally, the microprocessor 113 may be further configured to receive the pressure signal 109 from the pressure sensor 36 and stop sending the supply signal 111 to the pump 28 when the pressure inside the buffer tank 18 is greater than, or equal to, the preset value.

The microprocessor 113 may be associated with a memory 115, such as read only memory (ROM) 108, for storing a program or programs, and a random access memory (RAM) 110 which serves as a working area for use in executing the programs stored in memory 45. The ROM 108 may be further configured to store values, such as the preset value, and the RAM 110 may be utilized to access the stored preset value in ROM 108 and determine whether or not to continue to supply send out the supply signal 111 to the pump 28.

As alluded to above, but not explicitly described, the pump may be operatively electronically coupled to the controller 34 of the control system 107. As such, the pump 28 may send out the pressurized-liquid-stream 26 of the first material toward the vaporizer 22 in response to receiving the supply signal 111 from the controller 34. Additionally, such pump 28 is configured to stop propelling the pressurized-liquid-stream 26 of the first material toward the vaporizer 22 when it stops receiving the supply signal 111 from the electronic controller 34.

### INDUSTRIAL APPLICABILITY

In operation, the teachings of the present disclosure can find applicability in many industrial applications, such as, but not limited to, the vaporizing system 10 of the gas supply system 98 of the semiconductor manufacturing process described above. The vaporizing system 10 of the gas supply system 98 may be directed to gases including, but not limited to, oxygen (O₂), nitrogen (N₂), Argon (Ar), carbon dioxide (CO₂), supercritical carbon dioxide (CO₂), and other gases known to be useful in semiconductor manufacturing processes. More specifically, in a first step of operating a gas system 98 to create a process-ready-gas-stream 104 for a semiconductor manufacturing process 12 includes fluidly coupling a liquid material tank 100 configured to store a first-material in a liquid state with a second-liquid-conduit 32 configured to convey a non-pressurized-liquid-stream 30 of the first-material, wherein the second-liquid-conduit 32 is positioned fluidly downstream of the liquid material tank 100.

Next, the method of operation includes fluidly coupling the second-liquid-conduit 32 configured to convey the non-pressurized-liquid-stream 30 of the first-material with a pump 28. The pump 28 may be configured to receive the non-pressurized-liquid-stream 30 of the first-material and send-out a pressurized-liquid-stream 26 of the first-material, and the pump 28 is positioned fluidly downstream of the second-liquid-conduit 32. This method also includes fluidly coupling the pump 28 configured to send-out the pressurized-liquid-stream 26 of the first-material with a first-liquid-conduit 24 configured to convey the pressurized-liquid-stream 26 of the first-material. The first-liquid-conduit 24 may be positioned fluidly downstream of the pump 28. Additionally, the method comprises fluidly coupling the first-liquid-conduit 24 configured to convey the pressurized-liquid-stream 26 of the first-material to a vaporizer 22 that is configured to induce a phase change of the first-material from a liquid state to a gaseous state and thereby create a gas-stream 16 of the first material. The vaporizer 22 may be positioned fluidly downstream of first-liquid-conduit 24.

Moving on, this method includes fluidly coupling the vaporizer 22 configured to induce a phase change of the first-material from a liquid state to a gaseous state and thereby create a gas-stream 16 of the first material with a second-gas-conduit 20 configured to convey the gas-stream 16, wherein the second-gas-conduit 20 is positioned fluidly downstream of the vaporizer 22. In another step, the second-gas-conduit 22 configured to convey the gas-stream 16 is fluidly coupled with a buffer tank 18 that is configured to store the first-material in a gaseous-state, and wherein the buffer tank 18 is positioned fluidly downstream of the second-gas-conduit 22. This method may also incorporate fluidly coupling the buffer tank 18 with a first-gas-conduit 14 configured to convey the gas-stream 16 with a pressure control and purification system 102 configured to receive the gas-stream 16 and generate a process-ready-gas-stream 104 for the semiconductor manufacturing process 12. The pressure control and purification system 102 is located fluidly downstream of the first-gas-conduit 14. In another step of this process, the buffer tank 18 is fluidly coupled with a process-ready-gas-conduit 106 configured to convey the process-ready-gas-stream 104 towards the semiconductor manufacturing process 12, wherein the process-ready-gas-conduit is positioned fluidly downstream of the process-ready-gas-conduit 106.

The semiconductor manufacturing process 12 may be fluidly coupled with the process-ready-gas-conduit 106 configured to convey the process-ready-gas-stream 104 towards the semiconductor manufacturing process 12, and the semiconductor manufacturing process 12 is positioned fluidly downstream of the process-ready-gas-conduit 106. A pressure sensor 36 may be associated with the buffer tank 18 that is configured to transmit a pressure signal 109 to the electronic controller 34 while the pressure sensor 36 detects that the pressure of the first-material in the buffer tank 18 is less than a predetermined low-pressure value. The electronic controller 34 is further configured to transmit a supply signal 111 to the pump 28 while the pressure of the first-material in the buffer tank 18 is less than a predetermined low-pressure value and thereby propel the first-material toward the remainder of the gas supply system 98, and wherein the electronic controller 34 is additionally configured to stop sending the supply signal 111 to the pump 28 when the pressure of the first-material in the buffer tank 18 is greater than, or equal to, the predetermined low-pressure value.

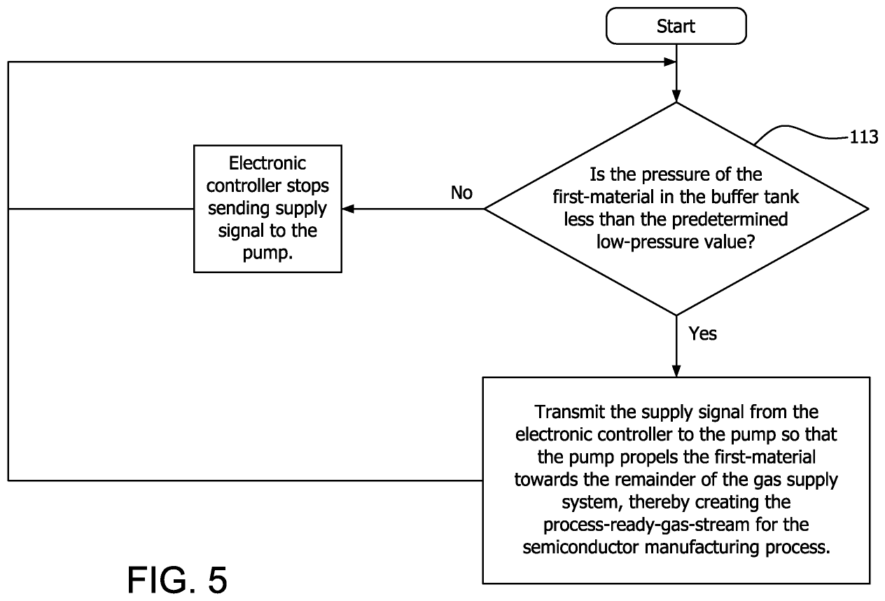

FIG. 5 is flowchart depicting an exemplary set of steps of the control system 107 of the gas supply system 98 manufactured in accordance with FIGS. 1-4. As seen there, at step 113 the electronic controller 34 may receive the pressure signal 109 from the pressure sensor 36 and determine whether the pressure of the first-material in the buffer tank 18 is less than the predetermined low-pressure value. If the pressure of the first-material in the tank 18 is greater than, or equal to, the predetermined low-pressure value, then the electronic controller 34 stops sending the supply signal 111 to the pump 28. Alternatively, if the pressure of the first-material in the buffer tank 18 is less than the predetermined low-pressure value, then electronic controller 34 will transmit the supply signal 111 to the pump 28 so that the pump 28 propels the first-material towards the remainder of the gas supply system 98, thereby creating the process-ready-gas-stream 104 for the semiconductor manufacturing process 12.

The pump 28 utilized in this method may be a hydraulically-actuated-diaphragm-pump, comprising a fluid-end 38 adjacent a power-end 40, wherein the fluid-end 38 is configured to allow the flow of the non-pressurized-liquid-stream 30 of the first-material through an inlet-port 42 into a fluid-end-chamber 44. The fluid-end 38 may be further configured to allow the flow of the pressurized-liquid-stream 26 of the first-material out of the fluid-end-chamber 44 through an outlet-port 46.

The power-end 40 may be further configured to conduct work on the non-pressurized-liquid-stream 30 of the first-material residing inside the fluid-end-chamber 44 and thereby create the pressurized-liquid-stream 26 of the first-material by the action of a hydraulically-actuated-diaphragm 48.

The hydraulically-actuated-diaphragm 48 may be reciprocally attached to the power-end 40, and may actuate between a diaphragm-resting-state that exists while a return-spring 50 of the hydraulically-actuated-diaphragm 48 is in a non-tensioned position and a diaphragm 52 is abutting a power-end-fluid-chamber-wall 54, and a diaphragm-pressurization-state that exists while the return-spring 50 is in a tensioned position and at least a portion of a diaphragm 52 extends past a pressurization-line 56 that is defined as a plane extending through the location where the fluid-end 38 abuts the power-end 40. The hydraulically-actuated-diaphragm 48 is designed to conduct work on the non-pressurized-liquid-stream 30 of the first-material residing inside the fluid-end-chamber 44 and thereby create the pressurized-liquid-stream 26 of the first-material when actuated from the diaphragm-resting-state to the diaphragm-pressurization-state.

The hydraulically-actuated-diaphragm 48 of this method may further comprise a front-side 58 in contact with the first-material and a back-side 60 opposite the front-side 58 in contact with a hydraulic-fluid 61 held inside a power-end-hydraulic-chamber 62. The pump can further include an orifice 64 extending between the power-end-hydraulic-chamber 62 and the back-side 60 configured to transfer the hydraulic-fluid 61 to the back-side 60 while the hydraulic-fluid 61 is under pressure inside the power-end-hydraulic-chamber 62.

The power-end 40 of the pump 28 may further comprise a separation-wall 66 dividing the power-end-hydraulic-chamber 62 from an overflow-chamber 68 having a front-end 70 neighboring the power-end-hydraulic-chamber 62 and a back-end 72 opposite the front-end 70 neighboring the overflow-chamber 68, a bore 74 extending through the separation-wall 66 between the front-end 70 and the back-end 72. A plunger 76 of the pump 28 may reciprocally engage with the bore 74, and further comprise a crankshaft 78 rotationally powered by a motor, a connecting-rod 80 operatively coupled to the plunger 76 at its first-end 82 and further be operatively coupled to the crankshaft 78 at its second-end 84.

The reciprocally engaging plunger 76 of the pump 28 may actuate between a plunger-resting-state that exists while the second-end 84 of the connecting-rod 80 is positioned at a location furthest away from the front-end 70 of the separation-wall 66 and a plunger-pressurization-state that exists while the second-end 84 of the connecting-rod 80 is positioned at a location closest to the front-end 70 of the separation-wall 66. The reciprocally engaging plunger 76 is configured to conduct work on the hydraulic-fluid 61 inside the power-end-hydraulic-chamber 62 while transitioning from the plunger-resting-state to the plunger-pressurization state, thereby propelling hydraulic-fluid 61 located inside the power-end-hydraulic-chamber 62 through the orifice 64 to the back-side 60 of the hydraulically-actuated-diaphragm 58. This in turn may actuate the hydraulically-actuated-diaphragm 58 between the diaphragm-resting-state and diaphragm-pressurization-state, thereby conducting work on the non-pressurized-liquid-stream 30 of the first-material residing inside the fluid-end-chamber 44 and thereby creates the pressurized-liquid-stream 26 of the first-material inside the fluid-end-chamber 44.

This pump 28 of this method may further comprise a first-check-valve 86 associated with the inlet-port 42 and be configured to allow flow of the non-pressurized-liquid-stream 30 into the fluid-end-chamber 44 while the pressure of the first-material inside the fluid-end-chamber 44 is less than, or equal to, a first-predetermined-value. The pump 28 may also comprise second-check-valve 88 associated the outlet-port 46 that is configured to allow flow of the pressurized-liquid-stream 26 of the first-material out of the fluid-end-chamber 44 while the pressure of the first-material inside the fluid-end-chamber 44 is greater than, or equal to, a second-predetermined-value. The second-predetermined value is greater than the first-predetermined-value. A third-check-valve 90 may be associated with a hydraulic-fluid-inlet-port 92 that is configured to allow flow of the hydraulic-fluid 61 into the power-end-hydraulic-chamber 62 while the pressure of the hydraulic-fluid 61 inside the power-end-hydraulic-chamber 62 is less than, or equal to, a third-predetermined-value. A fourth-check-valve 94 may be associated with a hydraulic-fluid-outlet-port 96 that is configured to allow flow of the hydraulic-fluid 61 out of the power-end-hydraulic-chamber 62 while the pressure of the hydraulic-fluid 61 inside the power-end-hydraulic-chamber 62 is greater than, or equal to, a fourth-predetermined-value. The fourth-predetermined-value is greater than the third-predetermined-value.

The above description is meant to be representative only, and thus modifications may be made to the aspects of the invention disclosed herein without departing from the scope of the disclosure. Thus, these modifications fall within the scope of the present disclosure and are intended to fall within the appended claims.

What is claimed is:

1. A vaporizing system for a semiconductor manufacturing process, comprising:
a first-gas-conduit configured to convey a gas-stream of a first-material toward the semiconductor manufacturing process;
a buffer tank upstream of and fluidly coupled to the first-gas-conduit configured to store the first-material in a gaseous state at, or above, a predetermined low-pressure-value;
a second-gas-conduit upstream of and fluidly coupled to the buffer tank configured to convey the gas-stream of the first material toward the buffer tank;
a vaporizer upstream of and fluidly coupled to the second-gas-conduit configured to induce a phase change of the first-material from a liquid state to a gaseous state and thereby create the gas-stream of the first-material;
a first-liquid-conduit upstream of and fluidly coupled to the vaporizer configured to convey a pressurized-liquid-stream of the first-material toward the vaporizer;
a pump upstream of and fluidly coupled to the first-liquid-conduit configured to receive a non-pressurized-liquid-stream of the first-material and send out the pressurized-liquid-stream of the first material, thereby propelling the first-material toward the vaporizer; and
a second-liquid-conduit upstream of and fluidly coupled to the pump configured to convey the non-pressurized-liquid-stream of the first-material to the pump.

2. The vaporizing system for a semiconductor manufacturing process according to claim 1, further comprising an electronic controller configured to receive a low-pressure-signal and transmit a supply signal to the pump in response to the low-pressure-signal, and further comprising a pressure sensor associated with the buffer tank configured to transmit the low-pressure-signal to the electronic controller when it detects that the pressure of the first-material in the buffer tank is less than the predetermined low-pressure-value.

3. The vaporizing system for a semiconductor manufacturing process according to claim 2, wherein the pump is configured to propel the first-material toward the remainder of the vaporizing system while receiving the supply signal from the electronic controller, and stop propelling the first-material toward the remainder of the vaporizing system when it does not receive the supply signal from the electronic controller.

4. The vaporizing system for a semiconductor manufacturing process according to claim 1, wherein the pump is a hydraulically-actuated-diaphragm-pump, comprising a fluid-end adjacent a power-end, wherein the fluid-end is configured to allow the flow of the non-pressurized-liquid-stream of the first-material through an inlet-port into a fluid-end-chamber, and wherein the fluid-end is further configured to allow the flow of the pressurized-liquid-stream of the first-material out of the fluid-end-chamber through an outlet-port, and the power-end is configured to conduct work on the non-pressurized-liquid-stream of the first-material residing inside the fluid-end-chamber and thereby create the pressurized-liquid-stream of the first-material by the action of a hydraulically-actuated-diaphragm.

5. The vaporizing system for a semiconductor manufacturing process according to claim 4, wherein the hydraulically-actuated-diaphragm is reciprocally attached to the power-end, and may actuate between a diaphragm-resting-state that exists while a return-spring of the hydraulically-actuated-diaphragm is in a non-tensioned position and a diaphragm is abutting a power-end-fluid-chamber-wall, and a diaphragm-pressurization-state that exists while the return-spring is in a tensioned position and at least a portion of a diaphragm extends past a pressurization-line that is defined as a plane extending through the location where the fluid-end abuts the power-end.

6. The vaporizing system for a semiconductor manufacturing process according to claim 5, wherein the hydraulically-actuated-diaphragm conducts work on the non-pressurized-liquid-stream of the first-material residing inside the fluid-end-chamber and thereby creates the pressurized-liquid-stream of the first-material when actuated from the diaphragm-resting-state to the diaphragm-pressurization-state.

7. The vaporizing system for a semiconductor manufacturing process according to claim 6, wherein the hydraulically-actuated-diaphragm further comprises a front-side in contact with the first-material, a back-side opposite the front-side in contact with a hydraulic-fluid held inside a power-end-hydraulic-chamber, an orifice extending between the power-end-hydraulic-chamber and the back-side configured to transfer the hydraulic-fluid to the back-side while the hydraulic-fluid is under pressure inside the power-end-hydraulic-chamber.

8. The vaporizing system for a semiconductor manufacturing process according to claim 7, wherein the power-end further comprises a separation-wall dividing the power-end-hydraulic-chamber from an overflow-chamber having a front-end neighboring the power-end-hydraulic-chamber and a back-end opposite the front-end neighboring the overflow-chamber, a bore extending through the separation-wall between the front-end and the back-end, a plunger reciprocally engaged with the bore, a crankshaft rotationally powered by a motor, a connecting-rod operatively coupled to the plunger at its first-end and further operatively coupled to the crankshaft at its second-end.

9. The vaporizing system for a semiconductor manufacturing process according to claim 8, wherein the reciprocally engaging plunger may actuate between a plunger-resting-state that exists while the second-end of the connecting-rod is positioned at a location furthest away from the front-end of the separation-wall and a plunger-pressurization-state that exists while the second-end of the connecting-rod is positioned at a location closest to the front-end of the separation-wall, and wherein the reciprocally engaging plunger conducts work on the hydraulic-fluid inside the power-end-hydraulic-chamber while transitioning from the plunger-resting-state to the plunger-pressurization state, thereby propelling hydraulic-fluid located inside the power-end-hydraulic-chamber through the orifice to the back-side of the hydraulically-actuated-diaphragm so that the hydraulically-actuated-diaphragm may actuate between the diaphragm-resting-state and diaphragm-pressurization-state, thereby conducting work on the non-pressurized-liquid-stream of the first-material residing inside the fluid-end-chamber and thereby create the pressurized-liquid-stream of the first-material inside the fluid-end-chamber.

10. The vaporizing system for a semiconductor manufacturing process according to claim 9, further comprising a first-check-valve associated with the inlet-port configured to allow flow of the non-pressurized-liquid-stream into the fluid-end-chamber while the pressure of the first-material inside the fluid-end-chamber is less than, or equal to, a first-predetermined-value, a second-check-valve associated the outlet-port configured to allow flow of the pressurized-liquid-stream of the first-material out of the fluid-end-chamber while the pressure of the first-material inside the fluid-end-chamber is greater than, or equal to, a second-predetermined-value, and wherein the second-predetermined value is greater than the first-predetermined-value, a third-check-valve associated with a hydraulic-fluid-inlet-port configured to allow flow of the hydraulic-fluid into the power-end-hydraulic-chamber while the pressure of the hydraulic-fluid inside the power-end-hydraulic-chamber is less than, or equal to, a third-predetermined-value, a fourth-check-valve associated with a hydraulic-fluid-outlet-port configured to allow flow of the hydraulic-fluid out of the power-end-hydraulic-chamber while the pressure of the hydraulic-fluid inside the power-end-hydraulic-chamber is greater than, or equal to, a fourth-predetermined-value, and wherein the fourth-predetermined-value is greater than the third-predetermined-value.

11. A gas supply system for a semiconductor manufacturing process, comprising:
a liquid material tank upstream of, and fluidly connected to, a second-liquid-conduit, wherein the liquid material tank is configured to store a first-material in a liquid state, and wherein the second-liquid-conduit is configured to convey a non-pressurized-liquid-stream of the first-material toward the remainder of the gas supply system;
a pressure control and purification system downstream of, and fluidly connected to a first-gas-conduit, wherein the pressure control and purification system is configured to receive a gas-stream of the first-material through the first-gas-conduit and generate a process-ready-gas-stream has a pressure equivalent to a predetermined-manufacturing-process-pressure defined by the semiconductor manufacturing process, and wherein the process-ready-gas-stream further has a total-particle-count less than, or equal to, a predetermined particle-count defined by the semiconductor manufacturing process;
a process-ready-gas-conduit downstream of, and fluidly coupled to, the pressure control and purification system, and upstream of, and fluidly coupled to, the semiconductor manufacturing process that is configured to convey the process-ready-gas-stream from the pressure control and purification system to the semiconductor manufacturing process; and
a vaporizing system, comprising:
a buffer tank upstream of and fluidly coupled to the first-gas-conduit configured to store the first-material in a gaseous state at, or above, a predetermined low-pressure-value;
a second-gas-conduit upstream of and fluidly coupled to the buffer tank configured to convey the gas-stream of the first material toward the buffer tank;
a vaporizer upstream of and fluidly coupled to the second-gas-conduit configured to induce a phase change of the first-material from a liquid state to a gaseous state and thereby create the gas-stream of the first-material;
a first-liquid-conduit upstream of and fluidly coupled to the vaporizer configured to convey a pressurized-liquid-stream of the first-material toward the vaporizer;
a pump upstream of and fluidly coupled to the first-liquid-conduit configured to receive a non-pressurized-liquid-stream of the first-material and send out the pressurized-liquid-stream of the first material, thereby propelling the first-material toward the vaporizer; and
wherein the second-liquid-conduit is positioned upstream of and is fluidly coupled to the pump and is configured to convey the non-pressurized-liquid-stream of the first-material to the pump.

12. The gas supply system for a semiconductor manufacturing process according to claim 11, further comprising an electronic controller configured to receive a low-pressure-signal and transmit a supply signal to the pump in response to the low-pressure-signal, and further comprising a pressure sensor associated with the buffer tank configured to transmit the low-pressure-signal to the electronic controller when it detects that the pressure of the first-material in the buffer tank is less than the predetermined low-pressure-value.

13. The gas supply system for a semiconductor manufacturing process according to claim 12, wherein the pump is configured to propel the first-material toward the remainder of the vaporizing system while receiving the supply signal from the electronic controller, and stop propelling the first-material toward the remainder of the vaporizing system when it does not receive the supply signal from the electronic controller.

14. The gas supply system for a semiconductor manufacturing process according to claim 13, wherein the pump is a hydraulically-actuated-diaphragm-pump, comprising a fluid-end adjacent a power-end, wherein the fluid-end is configured to allow the flow of the non-pressurized-liquid-stream of the first-material through an inlet-port into a fluid-end-chamber, and wherein the fluid-end is further configured to allow the flow of the pressurized-liquid-stream of the first-material out of the fluid-end-chamber through an outlet-port, and the power-end is configured to conduct work on the non-pressurized-liquid-stream of the first-material residing inside the fluid-end-chamber and thereby create the pressurized-liquid-stream of the first-material by the action of a hydraulically-actuated-diaphragm.

15. The gas supply system for a semiconductor manufacturing process according to claim 14, wherein the hydraulically-actuated-diaphragm is reciprocally attached to the power-end, and may actuate between a diaphragm-resting-state that exists while a return-spring of the hydraulically-actuated-diaphragm is in a non-tensioned position and a diaphragm is abutting a power-end-fluid-chamber-wall, and a diaphragm-pressurization-state that exists while the return-spring is in a tensioned position and at least a portion of a diaphragm extends past a pressurization-line that is defined as a plane extending through the location where the fluid-end abuts the power-end.

16. The gas supply system for a semiconductor manufacturing process according to claim 15, wherein the hydraulically-actuated-diaphragm conducts work on the non-pressurized-liquid-stream of the first-material residing inside the fluid-end-chamber and thereby creates the pressurized-liquid-stream of the first-material when actuated from the diaphragm-resting-state to the diaphragm-pressurization-state.

17. The gas supply system for a semiconductor manufacturing process according to claim 16, wherein the hydraulically-actuated-diaphragm further comprises a front-side in contact with the first-material, a back-side opposite the front-side in contact with a hydraulic-fluid held inside a power-end-hydraulic-chamber, an orifice extending between the power-end-hydraulic-chamber and the back-side configured to transfer the hydraulic-fluid to the back-side while the hydraulic-fluid is under pressure inside the power-end-hydraulic-chamber.

18. The gas supply system for a semiconductor manufacturing process according to claim 17, wherein the power-end further comprises a separation-wall dividing the power-end-hydraulic-chamber from an overflow-chamber having a front-end neighboring the power-end-hydraulic-chamber and a back-end opposite the front-end neighboring the overflow-chamber, a bore extending through the separation-wall between the front-end and the back-end, a plunger reciprocally engaged with the bore, a crankshaft rotationally powered by a motor, a connecting-rod operatively coupled to the plunger at its first-end and further operatively coupled to the crankshaft at its second-end

19. The gas supply system for a semiconductor manufacturing process according to claim 18, wherein the reciprocally engaging plunger may actuate between a plunger-resting-state that exists while the second-end of the connecting-rod is positioned at a location furthest away from the front-end of the separation-wall and a plunger-pressurization-state that exists while the second-end of the connecting-rod is positioned at a location closest to the front-end of the separation-wall, and wherein the reciprocally engaging plunger conducts work on the hydraulic-fluid inside the power-end-hydraulic-chamber while transitioning from the plunger-resting-state to the plunger-pressurization state, thereby propelling hydraulic-fluid located inside the power-end-hydraulic-chamber through the orifice to the back-side of the hydraulically-actuated-diaphragm so that the hydraulically-actuated-diaphragm may actuate between the diaphragm-resting-state and diaphragm-pressurization-state, thereby conducting work on the non-pressurized-liquid-stream of the first-material residing inside the fluid-end-chamber and thereby create the pressurized-liquid-stream of the first-material inside the fluid-end-chamber.

20. The gas supply system for a semiconductor manufacturing process according to claim 19, further comprising a first-check-valve associated with the inlet-port configured to allow flow of the non-pressurized-liquid-stream into the fluid-end-chamber while the pressure of the first-material inside the fluid-end-chamber is less than, or equal to, a first-predetermined-value, a second-check-valve associated the outlet-port configured to allow flow of the pressurized-liquid-stream of the first-material out of the fluid-end-chamber while the pressure of the first-material inside the fluid-end-chamber is greater than, or equal to, a second-predetermined-value, and wherein the second-predetermined value is greater than the first-predetermined-value, a third-check-valve associated with a hydraulic-fluid-inlet-port configured to allow flow of the hydraulic-fluid into the power-end-hydraulic-chamber while the pressure of the hydraulic-fluid inside the power-end-hydraulic-chamber is less than, or equal to, a third-predetermined-value, a fourth-check-valve associated with a hydraulic-fluid-outlet-port configured to allow flow of the hydraulic-fluid out of the power-end-hydraulic-chamber while the pressure of the hydraulic-fluid inside the power-end-hydraulic-chamber is greater than, or equal to, a fourth-predetermined-value, and wherein the fourth-predetermined-value is greater than the third-predetermined-value.

21. A method of operating a gas supply system to create a process-ready-gas-stream for a semiconductor manufacturing process, comprising:
fluidly coupling a liquid material tank configured to store a first-material in a liquid state with a second-liquid-conduit configured to convey a non-pressurized-liquid-stream of the first-material, wherein the second-liquid-conduit is positioned fluidly downstream of the liquid material tank;
fluidly coupling the second-liquid-conduit configured to convey the non-pressurized-liquid-stream of the first-material with a pump that is configured to receive the non-pressurized-liquid-stream of the first-material and send-out a pressurized-liquid-stream of the first-material, wherein the pump is positioned fluidly downstream of the second-liquid-conduit;
fluidly coupling the pump configured to send-out the pressurized-liquid-stream of the first-material with a first-liquid-conduit configured to convey the pressurized-liquid-stream of the first-material, wherein the first-liquid-conduit is positioned fluidly downstream of the pump;
fluidly coupling the first-liquid-conduit configured to convey the pressurized-liquid-stream of the first-material to a vaporizer that is configured to induce a phase change of the first-material from a liquid state to a gaseous state and thereby create a gas-stream of the first material, wherein the vaporizer is positioned fluidly downstream of first-liquid-conduit;
fluidly coupling the configured to induce a phase change of the first-material from a liquid state to a gaseous state and thereby create a gas-stream of the first material with a second-gas-conduit configured to convey the gas-stream, wherein the second-gas-conduit is positioned fluidly downstream of the vaporizer;
fluidly coupling the second-gas-conduit configured to convey the gas-stream with a buffer tank configured to store the first-material in a gaseous-state, wherein the buffer tank is positioned fluidly downstream of the second-gas-conduit;
fluidly coupling the buffer tank with a first-gas-conduit configured to convey the gas-stream with a pressure control and purification system configured to receive the gas-stream and generate a process-ready-gas-stream for the semiconductor manufacturing process, wherein the pressure control and purification system is positioned fluidly downstream of the first-gas-conduit;
fluidly coupling the buffer tank with a process-ready-gas-conduit configured to convey the process-ready-gas-stream towards the semiconductor manufacturing process, wherein the process-ready-gas-conduit is positioned fluidly downstream of the process-ready-gas-conduit;
fluidly coupling the semiconductor manufacturing process with the process-ready-gas-conduit configured to convey the process-ready-gas-stream towards the semiconductor manufacturing process, wherein the semiconductor manufacturing process is positioned fluidly downstream of the process-ready-gas-conduit;
associating a pressure sensor with the buffer tank configured to transmit a pressure signal to an electronic controller, wherein the electronic controller is configured to transmit a supply signal to the pump while the pressure of the first-material in the buffer tank is less than a predetermined low-pressure value and thereby propel the first-material toward the remainder of the gas supply system, and wherein the electronic controller is configured to stop sending the supply signal to the pump when the pressure of the first-material in the buffer tank is greater than, or equal to, the predetermined low-pressure value.

22. The method of operating a gas supply system to create a process-ready-gas-stream for a semiconductor manufacturing process according to claim 21, wherein the pump is configured to propel the first-material toward the remainder of the vaporizing system while receiving the supply signal from the electronic controller, and stop propelling the first-material toward the remainder of the vaporizing system when it does not receive the supply signal from the electronic controller.

23. The gas supply system for a semiconductor manufacturing process according to claim 22, wherein the pump is a hydraulically-actuated-diaphragm-pump, comprising a fluid-end adjacent a power-end, wherein the fluid-end is configured to allow the flow of the non-pressurized-liquid-stream of the first-material through an inlet-port into a fluid-end-chamber, and wherein the fluid-end is further configured to allow the flow of the pressurized-liquid-stream of the first-material out of the fluid-end-chamber through an outlet-port, and the power-end is configured to conduct work on the non-pressurized-liquid-stream of the first-material residing inside the fluid-end-chamber and thereby create the pressurized-liquid-stream of the first-material by the action of a hydraulically-actuated-diaphragm.

24. The method of operating a gas supply system to create a process-ready-gas-stream for a semiconductor manufacturing process according to claim 23, wherein the hydraulically-actuated-diaphragm is reciprocally attached to the power-end, and may actuate between a diaphragm-resting-state that exists while a return-spring of the hydraulically-actuated-diaphragm is in a non-tensioned position and a diaphragm is abutting a power-end-fluid-chamber-wall, and a diaphragm-pressurization-state that exists while the return-spring is in a tensioned position and at least a portion of a diaphragm extends past a pressurization-line that is defined as a plane extending through the location where the fluid-end abuts the power-end.

25. The method of operating a gas supply system to create a process-ready-gas-stream for a semiconductor manufacturing process according to claim 24, wherein the hydraulically-actuated-diaphragm conducts work on the non-pressurized-liquid-stream of the first-material residing inside the fluid-end-chamber and thereby creates the pressurized-liquid-stream of the first-material when actuated from the diaphragm-resting-state to the diaphragm-pressurization-state.

26. The method of operating a gas supply system to create a process-ready-gas-stream for a semiconductor manufacturing process according to claim 25, wherein the hydraulically-actuated-diaphragm further comprises a front-side in contact with the first-material, a back-side opposite the front-side in contact with a hydraulic-fluid held inside a power-end-hydraulic-chamber, an orifice extending between the power-end-hydraulic-chamber and the back-side configured to transfer the hydraulic-fluid to the back-side while the hydraulic-fluid is under pressure inside the power-end-hydraulic-chamber.

27. The method of operating a gas supply system to create a process-ready-gas-stream for a semiconductor manufacturing process according to claim 26, wherein the power-end further comprises a separation-wall dividing the power-end-hydraulic-chamber from an overflow-chamber having a front-end neighboring the power-end-hydraulic-chamber and a back-end opposite the front-end neighboring the overflow-chamber, a bore extending through the separation-wall between the front-end and the back-end, a plunger reciprocally engaged with the bore, a crankshaft rotationally powered by a motor, a connecting-rod operatively coupled to the plunger at its first-end and further operatively coupled to the crankshaft at its second-end.

28. The method of operating a gas supply system to create a process-ready-gas-stream for a semiconductor manufacturing process according to claim 27, wherein the reciprocally engaging plunger may actuate between a plunger-resting-state that exists while the second-end of the connecting-rod is positioned at a location furthest away from the front-end of the separation-wall and a plunger-pressurization-state that exists while the second-end of the connecting-rod is positioned at a location closest to the front-end of the separation-wall, and wherein the reciprocally engaging plunger conducts work on the hydraulic-fluid inside the power-end-hydraulic-chamber while transitioning from the plunger-resting-state to the plunger-pressurization state, thereby propelling hydraulic-fluid located inside the power-end-hydraulic-chamber through the orifice to the back-side of the hydraulically-actuated-diaphragm so that the hydraulically-actuated-diaphragm may actuate between the diaphragm-resting-state and diaphragm-pressurization-state, thereby conducting work on the non-pressurized-liquid-stream of the first-material residing inside the fluid-end-chamber and thereby create the pressurized-liquid-stream of the first-material inside the fluid-end-chamber.

29. The method of operating a gas supply system to create a process-ready-gas-stream for a semiconductor manufacturing process according to claim 28, further comprising a first-check-valve associated with the inlet-port configured to allow flow of the non-pressurized-liquid-stream into the fluid-end-chamber while the pressure of the first-material inside the fluid-end-chamber is less than, or equal to, a first-predetermined-value, a second-check-valve associated the outlet-port configured to allow flow of the pressurized-liquid-stream of the first-material out of the fluid-end-chamber while the pressure of the first-material inside the fluid-end-chamber is greater than, or equal to, a second-predetermined-value, and wherein the second-predetermined value is greater than the first-predetermined-value, a third-check-valve associated with a hydraulic-fluid-inlet-port configured to allow flow of the hydraulic-fluid into the power-end-hydraulic-chamber while the pressure of the hydraulic-fluid inside the power-end-hydraulic-chamber is less than, or equal to, a third-predetermined-value, a fourth-check-valve associated with a hydraulic-fluid-outlet-port configured to allow flow of the hydraulic-fluid out of the power-end-hydraulic-chamber while the pressure of the hydraulic-fluid inside the power-end-hydraulic-chamber is greater than, or equal to, a fourth-predetermined-value, and wherein the fourth-predetermined-value is greater than the third-predetermined-value.
